(19) United States
(12) Patent Application Publication
(10) Pub. No.: US 2009/0302109 A1
(43) Pub. Date: Dec. 10, 2009

(54) Protection Against Manipulation and Through-Drilling for an Apparatus to be Connected to an Electrical Circuit

(76) Inventors: Manfred Kerner, Erlenbach (DE); Eduard Maiterth, Heilbronn (DE)

Correspondence Address: BLANK ROME LLP, WATERGATE, 600 NEW HAMPSHIRE AVENUE, N.W., WASHINGTON, DC, 20037, US

(21) Appl. No.: 11/991,931

(22) PCT Filed: Sep. 13, 2006
(86) PCT No.: PCT/EP2006/008922

§ 371 Date: Mar. 5, 2009

(30) Foreign Application Priority Data
Sep. 13, 2005 (DE) 10 2005 043 640.4
Nov. 14, 2005 (DE) 10 2005 054 211.5
Aug. 21, 2006 (DE) 10 2006 039 136.5

(51) Int. Cl. G06K 7/00; H05K 1/00; H01L 23/58

(52) U.S. Cl. 235/439; 174/254

(57) ABSTRACT

A smart card reader having a housing in which contact elements are arranged which are adapted to contact a smart card, and adapted to be electrically connected to termination means wherein a protective grid is provided which encases the housing at least in an area where undesired manipulations are expected and wherein preferably also the termination means are encased.

The invention relates to means for protecting against manipulations and drilling operations in particular for an apparatus to be connected to an electrical circuit. Said apparatus is for instance a smart card reader, which is also called a smart card connector. Said apparatus might also be a magnetic card reading apparatus.

Smart card readers are used in many areas of technology so as to read information into the card, read information out of the card and to change information stored in the card.

It occurs that unauthorized persons try for various reasons to drill into or through the smart card reader.

It is an object of the invention to protect a smart card reader or an electrical or electronic apparatus against manipulations, in particular against drilling operations. Moreover, the occurrence of such an attempt to manipulate should be readily detectable and recordable.

The above mentioned object is attained in accordance with the invention by mounting a drilling protection/manipulation protection-grid (short: a protection grid) at the apparatus. The protection grid comprises conductor traces or conductors through which a current flows constantly or occasionally. The protective grid can be placed directly onto the smart card reader at one or more suitable locations. The conductors or conductive traces forming the protective grid are accessible from the outside of the smart card reader by means of contacts or contact zones so as to have currents or signals flow through the electrical conductors.

In accordance with an embodiment of the invention protection against manipulation is provided for a flex-print extending out of the smart card reader. The term “flex-print” is used as a short version for a flexible circuit or a flexible circuit board. In accordance with an embodiment of the invention the customary flexible circuit used for the connection to a smart card reader is provided with a plurality of layers, preferably three layers. This resulting flexible circuit of the invention will also be called a manipulation-detection-flexible-circuit or short a detection flexible circuit. The customary or current flexible circuit will be used in the detection flexible circuit for instance as a middle layer and will be referred to as termination connecting flexible circuit. Said middle layer serves with its two sides as a support for each one layer supporting a protective grid (protective grid elements).

For the connection to or connecting the termination of contact elements of a smart card reader and also for the connection to the protective grid elements a connection flexible circuit is provided. Preferably, on the upper surface of said connection flexible circuit a first protective grid element is provided. (First protective grid flexible circuit). On the bottom side of the connecting flexible circuit a second protective grid element is provided as a second protective layer. The second protective grid element is preferably in the form of a second protective grid flexible circuit.

The three layers which are preferably fixedly connected with each other form in accordance with the invention an integral manipulation protected detection flexible circuit.

Preferably, the connection flexible circuit forms together with the protective grid flexible circuits, which are provided on the top and the bottom an integral manipulation protected detection flexible circuit.

The detection flexible circuit of the first embodiment does not provide protection for the entire smart card reader system which comprises the smart card reader and its connecting means preferably in the form of a flexible circuit. The detection flexible circuit of the first embodiment provides protection only for the flexible connection circuit as such. As noted above, a protective grid could be directly mounted on the smart card reader, for instance it could be printed thereon.

In accordance with another embodiment of the invention protection is provided for the smart card reader itself as well as for the flexible connection circuit used for the connection to the smart card reader. This protection is provided by an encasing detection flexible circuit which encases the smart card reader in a manner that the smart card reader is protected against manipulation. Said encasing detection flexible circuit further protects the common flexible circuit against manipulations. In the second embodiment the customary or common flexible circuit providing for connection with the smart card reader can still be used.

Frequently magnetic card reading apparatus are used together with a smart card reader and are mounted thereon. The magnetic card reading apparatus as well as the connecting flexible circuit by means of which the magnetic card reading apparatus is connected to an electric apparatus can also be become victim of a manipulation. A further embodiment of the invention which is described in particular in FIGS. 19 to 27 deals with the problem of providing protection against the manipulation of a magnetic card reading apparatus using the principles of the first two embodiments.

Further advantages, objects and details of the invention can be gathered from the description of an embodiment according to the drawing; in the drawing

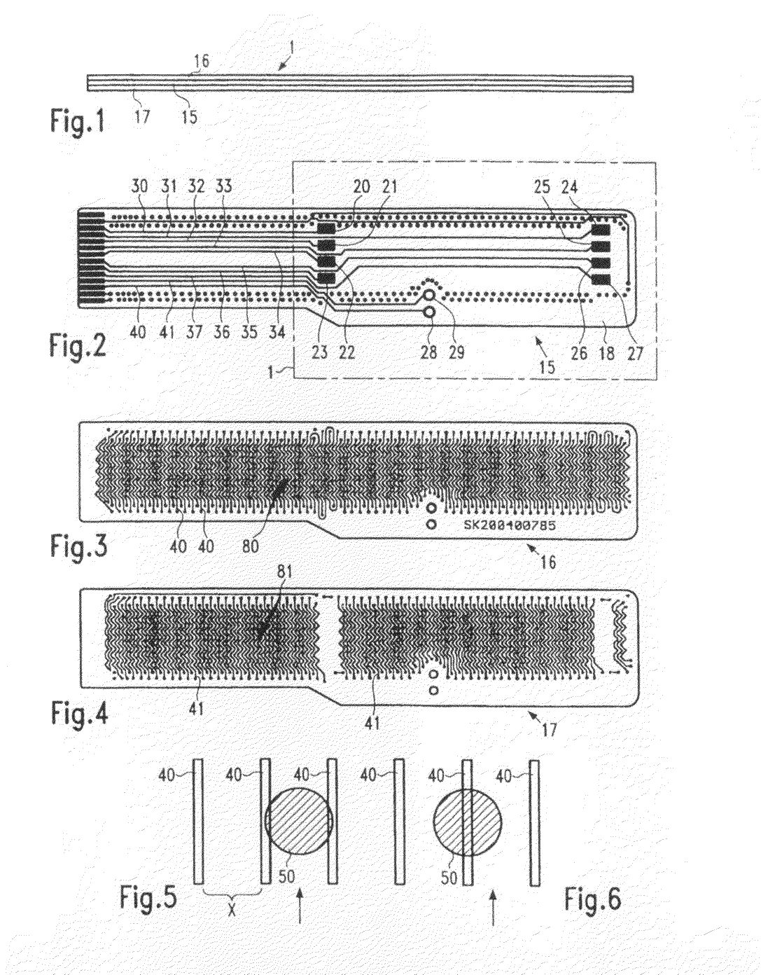

FIG. 1 is a side elevational view of the three layers of a detection flexible circuit of the invention:

FIG. 2 is a top plan view onto the upper surface of a connecting flexible circuit;

FIG. 3 is a top plan view of the first or upper protective grid flexible circuit;

FIG. 4 is a top plan view of the bottom layer, i.e. of the lower protection grid flexible circuit;

FIG. 5 discloses schematically a first kind of manipulation;

FIG. 6 shows schematically a second kind of manipulation;

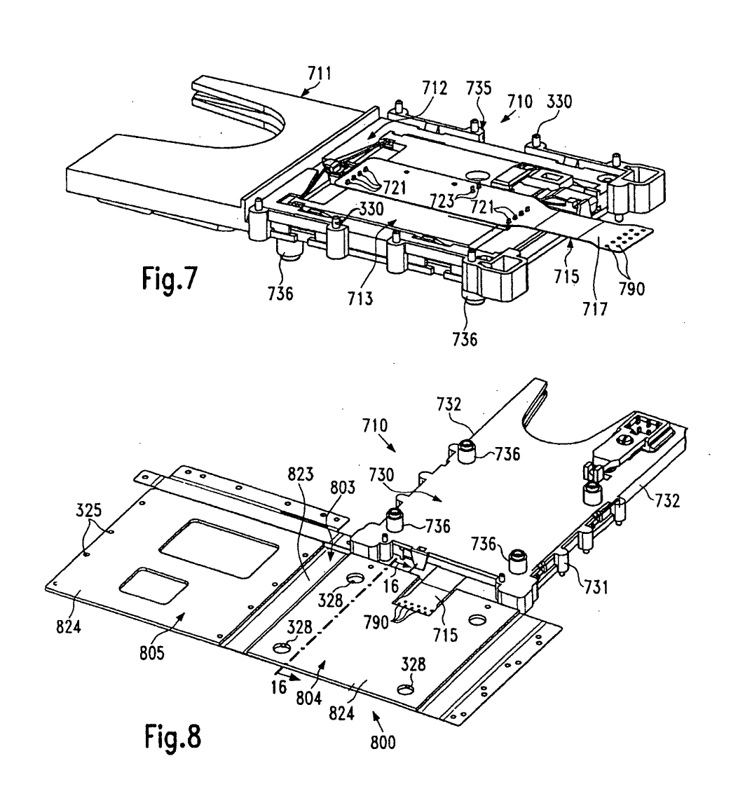

FIG. 7 is a perspective top plan view onto the upper surface of a smart card reader of the prior art with a customary connecting flexible circuit for the connection to the contact elements of the smart card reader;

FIG. 8 is a bottom plan view of the smart card reader of FIG. 7 together with an encasing flexible circuit according to the invention, said encasing flexible circuit being in a start position prior to carrying out the encasing operation;

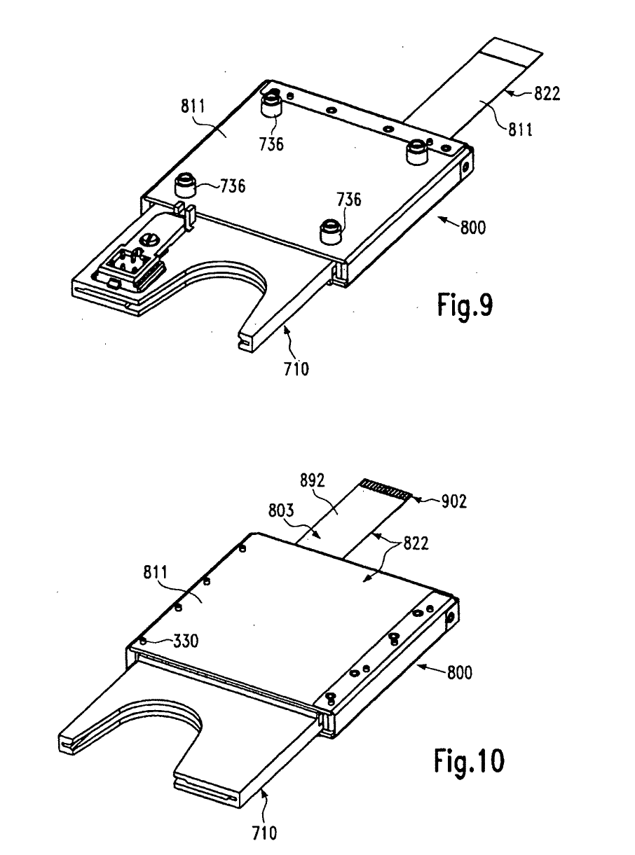

FIG. 9 is a perspective top plan view of the bottom side of the smart card reader encased by the encasing detection flexible circuit;

FIG. 10 is a top plan view onto the upper surface of the smart card reader of FIG. 1 in the encased condition of the smart card reader;

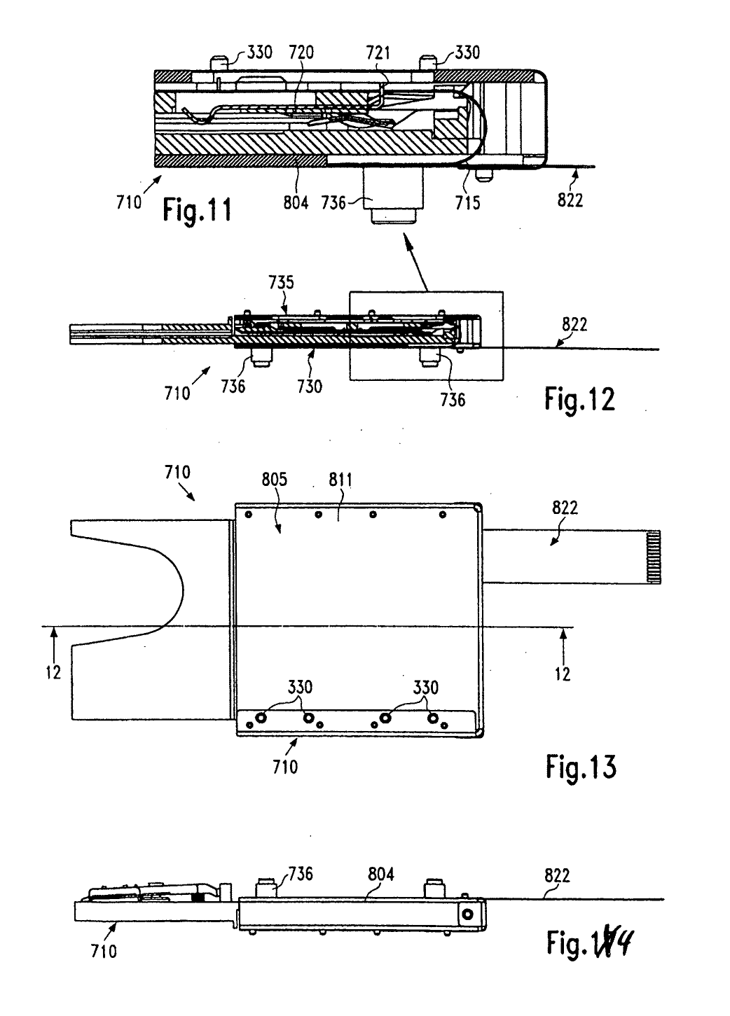

FIG. 11 is a detail of FIG. 12;

FIG. 12 is a sectional view in substance along line 12-12 of FIG. 13;

FIG. 13 is a top plan view onto the upper surface of the encased smart card reader of FIG. 7 (translator: FIG. 9);

FIG. 14 is a side elevation view of what is shown in FIG. 13;

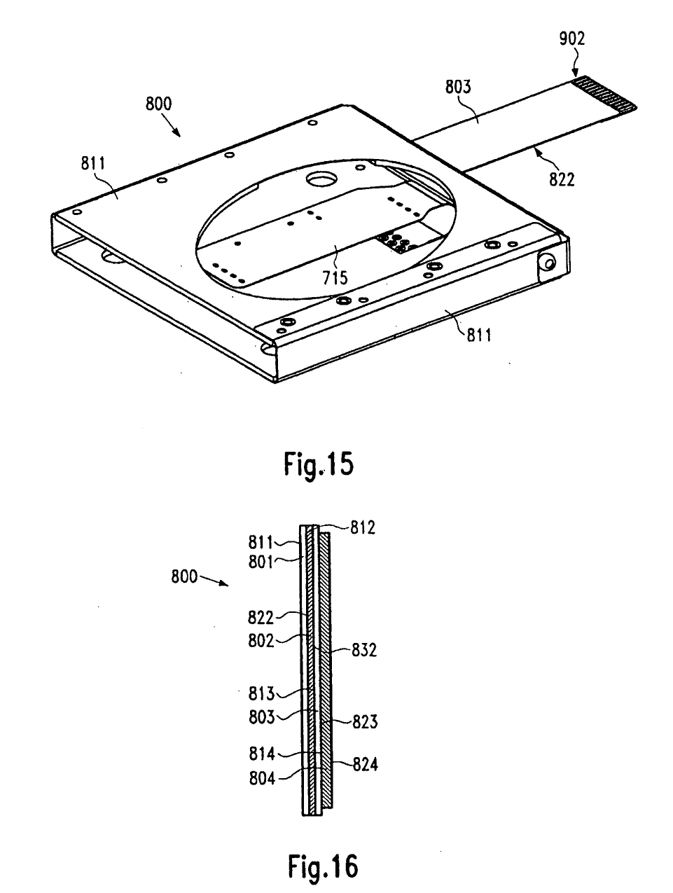

FIG. 15 is a representation of the encasing detection flexible circuit in its encasing position with the smart card reader being deleted, however, with the customary contact flexible circuit being shown together with its contact points for the connection with the encasing detection flexible circuit;

FIG. 16 is a sectional view of the encasing detection flexible circuit showing three flexible circuit layers and one reinforcement layer;

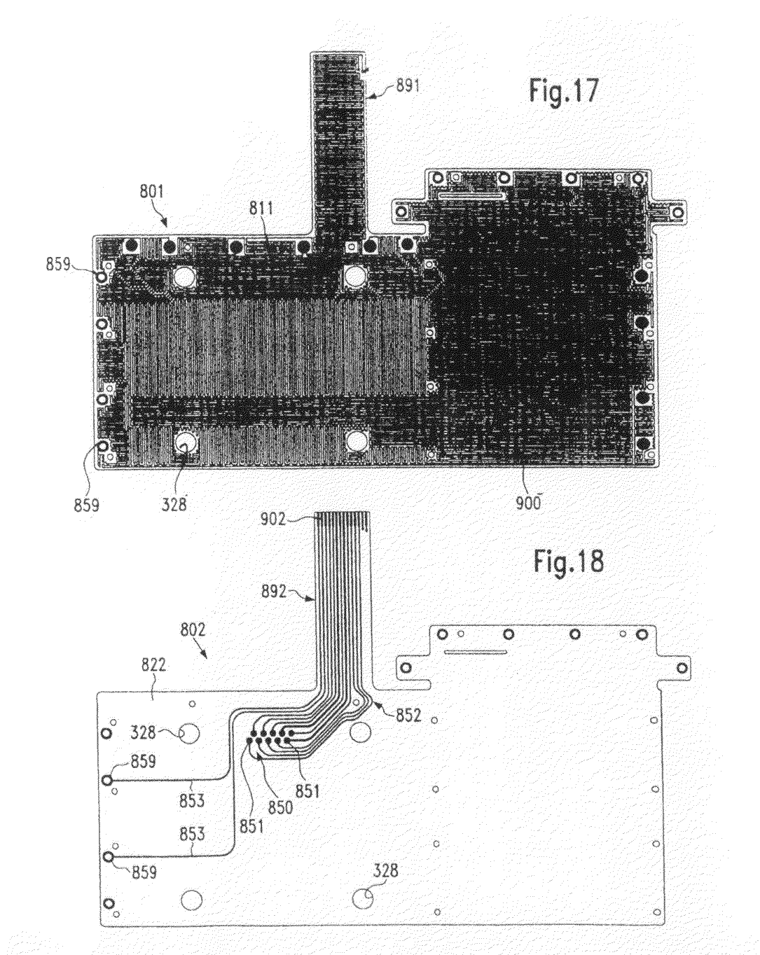

FIG. 17 shows one of the flexible circuit layers of FIG. 16, i.e. flexible circuit layer also called a protective flexible circuit layer, with FIG. 17 showing a top plan view onto the upper surface of said layer;

FIG. 18 is a top plan view of another flexible circuit layer of FIG. 16 with said flexible circuit layer being referred to as connection layer, with FIG. 18 showing the bottom side which is also called the solder side thereof;

FIG. 19 discloses another embodiment of the invention in a top plan view of a card reading apparatus protected against manipulations;

FIG. 20 shows a magnet card reading apparatus in accordance with FIG. 19 with the magnet head being shown;

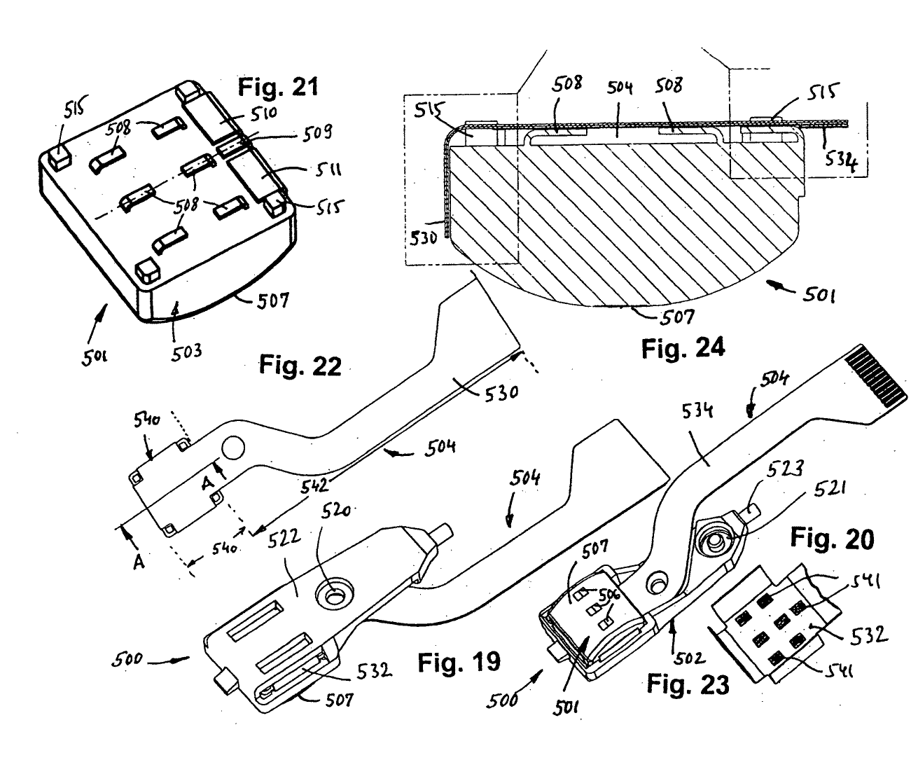

FIG. 21 is a perspective top plan view of the connecting side of the magnet head;

FIG. 22 is a top plan view of a connecting flexible circuit which is located at the bottom side of the magnet head 501 of FIG. 21;

FIG. 23 is a detail of FIG. 27 yet to be explained;

FIG. 24 is a sectional view along, line AA in FIG. 22;

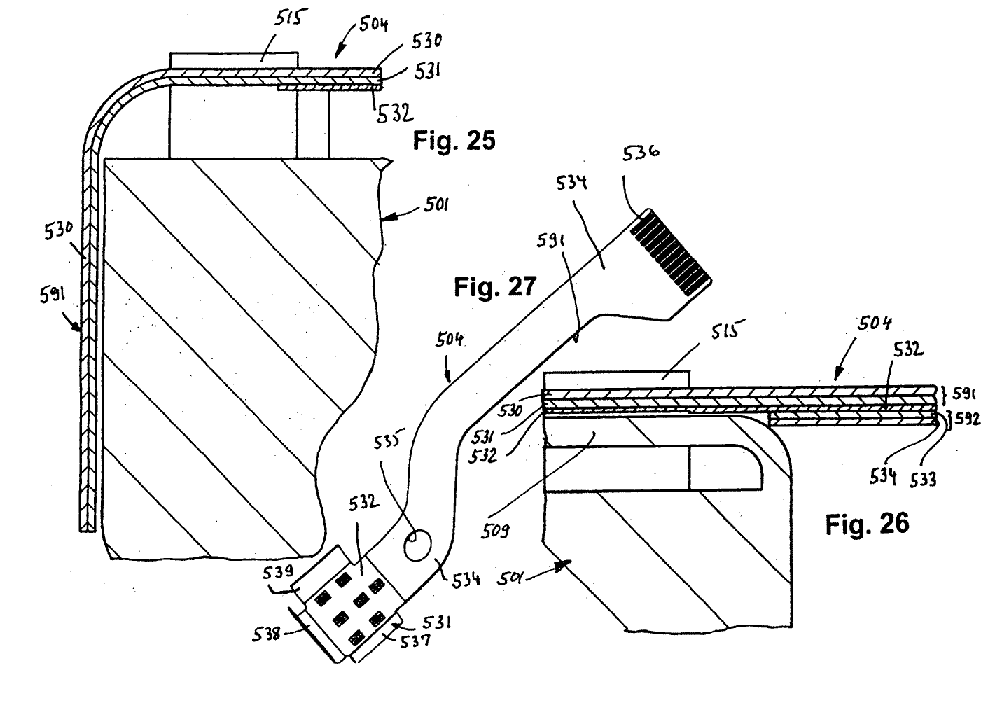

FIG. 25 shows an enlargement of the left area marked in FIG. 24;

FIG. 26 shows an enlargement of the right marked area; and

FIG. 27 is a top plan view of a connecting flexible circuit ready for receiving the reading head in accordance with FIG. 21.

FIG. 1 discloses a three-layer flexible circuit (flex-print) 1 (which will also be called below “detection flexible circuit”) which can provide a protected connection to a smart card reader 710, see also FIG. 2.

The three-layer detection flexible circuit 1 comprises, as is shown, preferably the following three layers or films which are glued together or which are formed integrally in a different manner. The three layers are: a first or upper layer 16 comprising a protective grid, said layer being also called a protective layer on also an upper protective grid flexible circuit 18; a second or bottom protective layer also referred to as lower protective grid flexible circuit 17; and a middle connecting layer also referred to as a connecting flexible circuit 15. The connecting flexible circuit 15 is also called a data transfer layer or a data transfer flexible circuit.

The connecting flexible circuit 15 comprises—as is customary—the required conductors or conductor paths 30 to 37 for contacting contact elements of the smart card reader 710. Said contacts 30 to 37 lead to contact pads 20, 21, 22, 23, 24, 25, 26 and 27 for connection with the smart card reader 710. The contact pads 20 to 27 are connected to contact pads 5 to 12 which are provided at a free end of the connecting flexible circuit 15 so as to connect the smart card reader 710 with an apparatus together with which the smart card reader 710 is to be used.

Moreover, the connecting flexible circuit 15 comprises contact surfaces or contact pads 1, 2 and 13, 14 on both sides and preferably aligned with the contact pads 5 through 12; said contact pads are connected with protective elements yet to be described, in particular to a protective grid 80 of the upper protective grid flexible circuit 16 as well as to the protective grid 81 of the bottom protective grid flexible circuit 17.

FIG. 2 discloses that spaced with respect to the contact pads 20 to 23 and 24 to 27 further contact pads 28, 29 are provided which are contacted via contact pads 3, 4. Said contact pads 28, 29 can be used for instance for connecting to a card presence switch provided in the smart card connector 710.

The protective grid flexible circuit 16 of FIG. 3 comprises the protective grid 81. The conductor paths or conductors 40 of the protective grid 81 extend in a zigzag pattern across the width of the protective grid flexible circuit 16.

Said different conductors 40 are preferably connected to contact pads 1, 2, 13 and 14 at the time the protective grid flexible circuit 16 is placed on the bottom side of the connecting flexible circuit 15, the upper surface of which is shown in FIG. 2.

So as to arrive at the three-layer detection flexible circuit 1 of the invention the lower protective grid flexible circuit 17 is fixed with its top surface shown in FIG. 4 at the bottom surface of the connecting flexible circuit 15. The conductors 41 forming the protective grid which is present in the lower protective grid flexible circuit 17 are contacted in a similar manner as is shown for the protective layer 16, and the connection is provided with the respective contact surfaces 1 or 2 or 13 or 14.

Thus, the connecting flexible circuit 15 of the three-layer detection flexible circuit 1 of the invention is used as a data transfer layer, while the protective grid flexible circuits 16 and 17 are connected by means of the connecting flexible circuit 15 to the outside or are connected further. The drilling protection provided in accordance with the present invention makes use of two parallel conductors having a different potential. The conductors 40, 41 of the protective grid flexible circuits 16 and 17 are spaced with a lateral width of 0.2 mm and are spaced from each other by 0.2 mm. The conductors 40 and 41 form continuous loops which preferably extend over the upper protective grid flexible circuit 16 and the lower protective grid flexible circuit 17. There is one conductor loop between the other having a different potential conductor loop. In case an attempt is made to penetrate by means of a drill, the protective grid flexible circuits 16 or 17, a short circuit occurs between the two conductors 40, 41, as is shown in FIG. 5 for conductor 40 or one of the conductors 14 is severed, as is shown in FIG. 6 also for a conductor 40.

The condition of the situation shown in FIGS. 5 and 6 can be detected by an appropriate electronic device which is connected to one or a plurality of the connectors to the contact pads 1, 2, 13, 14. According to the invention, protection is provided with respect to manipulations in a simple manner.

In the embodiment shown in FIGS. 1 to 6, a protective grid was provided only for the current flex-print or flexible circuit (customary connecting flexible circuit) for the connection of a smart card reader. The protective grid, in this case, was provided on the upper surface and on the bottom surface of the current flexible circuit. The current flex-print is a flex-print without protection against manipulation. According to the embodiment of FIG. 1, the protective grids had also the form of flexible circuits (flex-prints) with the three-layer detection flexible circuit 1 of FIG. 1 being the result.

In the introduction to the specification, the possibility is mentioned that the protective grid is provided directly on the smart card reader on one or a plurality of suitable locations. This possibility is advantageous insofar as the conductors or conductive paths forming the protective grid or the protective grids can be directly placed on the housing of the smart card reader in a space-saving manner.

In addition to the just mentioned embodiment of the invention which is not shown, also an extensive protection against manipulation of the smart card reader and the connection thereto can be obtained in particular in for the current connecting flexible circuit 15 in such a manner that a manipulation detection flexible circuit is provided. This manipulation detection flexible circuit protects the connection to the smart card reader, a connection which is preferably in the form of a customary connection flexible circuit, as well as the smart card reader itself with a better result as this is possible for the embodiment of FIGS. 1 to 4.

The embodiment of the invention shown in FIGS. 7 through 18 will now be explained. FIG. 7 shows in a top plan view the smart card reader or smart card connector 710 which is only partly (translator “not”) shown in FIG. 1. The smart card reader 710 comprises a housing 711. As is shown, the housing 711 can be, for instance, open at its top. A contact support frame 712 is inserted into the housing 711. Within the contact support frame 712, a reciprocally movable card sled 713 is mounted and can be moved by the insertion of a card (not shown). An arm-like spring biases the card sled 713 into the position shown in FIG. 7. Insertion of a card causes a movement of the card sled 713 in FIG. 7 rightward so as to provide for a contacting of the card.

In the card sled 713, the contact elements 720 shown in FIG. 11 are fixedly mounted. FIG. 7 discloses two spaced rows of termination or contacting ends 721. Moreover, contacting ends 723 are shown in FIG. 7 which serve to contact or terminate the contact elements of a card presence switch. The contacting or termination of the smart card connector 710 is obtained by means of a current flexible circuit 715 (also called a contact termination film or flexible circuit board for contacting the contact elements). The flexible circuit 715 is a “customary” or “current” flexible circuit (referred to by reference sign “1” in FIG. 1) as discussed in FIGS. 1 to 4. I.e., the flexible circuit 715 like the flexible circuit 1 is a flex-print without protection against manipulation. The flexible circuit 715 comprises a contacting or termination tongue 717 having preferably annular contacting or termination contact pads 790.

In accordance with this embodiment, an increased protection against manipulation is obtained not only for the current flexible circuit 715 but also for the smart card reader 710 in general by means of a detection flex-print 800 (also called detection flexible circuit). To differentiate with respect to the three-layer detection flexible circuit 1 of FIG. 1, the detection and contact flexible circuit according to this embodiment will be called an encasing detection flexible circuit.

FIG. 8 as well as FIGS. 15 through 18 disclose the encasing detection flexible circuit 800 in some detail. The encasing detection flexible circuit 800 comprises a reader-protective layer. The reader-protective layer is preferably a reader-protective flexible circuit 801 (which protects in particular the smart card reader),

a connecting layer, preferably a connecting flexible circuit 802 providing the required electrical connections, and
a connection protective layer, preferably a detection protective flexible circuit 803 protecting the connection. The axial encasing flexible circuit 800 is formed by the reader-protective flexible circuit 801, the connecting flexible circuit 802 and the connecting flexible circuit 803. The encasing detection flexible circuit 800 comprises an encasing flexible circuit connecting tongue 888, which is formed by the reader-protective flexible circuit 801, the connecting flexible circuit 802 and the connecting flexible circuit 803. The encasing flexible circuit contact tongue 888 is of a design which is secure against manipulations. The encasing flexible circuit connecting tongue 888 projects out of the smart card reader as is, for instance, shown in FIGS. 8, 9 and 13. The encasing detection flexible circuit 800 preferably comprises in addition a reinforcement layer, preferably in the form of two reinforcement elements 804 and 805. These three flexible circuits 801 to 803 are preferably integrally formed and are further preferably integrally formed together with the reinforcement elements 804 and 805.

The reader-protective flexible circuit 801 comprises a first side 811 and a second side 812. The first side 811 forms with respect to the smart card reader 710 the outer side.

The connecting flexible circuit 802 comprises a first side 822 and a second side 832.

Moreover, the connecting protective flexible circuit 803 comprises a first side 813 and a second side 823. Further, the reinforcement elements 804, 805 comprise first sides 814 as well as second sides 824.

In the reader-protective flexible circuit 801, one or more protective grids 900 are provided which are suitably connected and accessible from the outside for instance by conductors 950 formed in the plastic material of the flexible circuit similar to the conductors 40 in FIG. 3. It is clear that in order to obtain the protection against drilling, as shown in FIGS. 5 and 6, the conductors or conductor paths 40 in FIGS. 5 and 6 have to be a small spacing. Moreover, it is clear that the conductors or conductive paths 950 forming the protective grid 900 need to be accessible in a suitable manner via connecting or termination contact pads 902 (FIG. 15).

The protective grid(s) 900 are also present in a reader-protective flexible circuit connecting tongue 891 which is formed by the reader-protective flexible circuit 801.

Also, the common or contact element connecting pads 790 which are present in the customary or common connecting flexible circuit 715 (FIG. 7) need to be preferably contacted by conductors present in the connecting flexible circuit 802 via the connecting contact zones 902 (FIG. 15).

The connecting contact zones or pads are preferably at the free end of a connecting flexible circuit connecting zone 892 which is protectively covered by the reader-protective flexible circuit contact tongue 891.

For this purpose, conductors or conducting paths 852 are provided in the connecting flexible circuit 802 which are in connection with the connecting points 851 of a set of contact point connections 850. The conductors 853 are in connection with the protective grid 900 and they are also accessible from the outside by means of termination contact zones 902. The connecting or termination points 851 are connected with contact element connecting zones or contact points (pads) 790 of the flexible circuit board 750, preferably by means of soldering.

As shown in FIG. 16, the connecting or termination tongue 888 of the encasing detection flexible circuit 800 comprises in addition to the protection obtained by the connecting tongue 891 of the reader-protective flexible circuit 801 on the one side, also, on the other side of the connecting tongue 892 of the connecting flexible circuit 802, the protective connecting protection flexible circuit 803, at least in the area of the connecting tongue 892. This connecting protecting flexible circuit 803 does not need to cover the entire surface like the reader-protective flexible circuit 801 shown in FIG. 17 by one protective grid, but the connecting protective flexible circuit 803 needs to cover only at least an area of the connecting tongue 892. This is carried out by the connecting flexible circuit board tongue 892 shown in the embodiment represented by FIGS. 10 and 11. The protective grid(s) present in the connecting flexible circuit can preferably be electronically surveyed via the connecting zones 902.

By means of the connecting points or pads 859 at the circumference of the reader-protective flexible circuit 801 and the connecting protective flexible circuits 803, the protective grids in the two protective flexible circuits 801 and 803 can be connected and can both be contacted at the certain contacts of the contact set 902 via connectors 853, 859.

The method according to the invention for mounting the encasing detection flexible circuit 800 is as follows:

Firstly, the encasing detection flexible circuit board 800 is arranged as is shown in FIG. 8 such that the connecting tongue 717 of the flexible circuit board 715 with its contact pads 790 comes to be placed on the set 850 of contact pads and is soldered thereto. Thereupon, the encasing detection flexible circuit 800 is moved from the position shown in FIG. 8 by means of the stiffening or reinforcing elements 804, 805 by 180°, such that the one reinforcement element 804 comes to lie on the bottom side 730 of the smart card reader 710. In this process, the mounting posts 737, which are unitarily formed at the bottom side 730 of the housing 711 of the smart card reader 710, come into engagement with respective holes 328 in the encasing flexible circuit board 800. Then, the encasing detection flexible circuit 800 is folded with the other side supporting the reinforcement element 805 on to the upper surface 735 of the smart card reader 710, whereby the mounting holes 325 in the encasing detection flexible circuit 800 come into engagement with pins 330 provided at the housing 711 of the smart card reader 710. Finally, the remaining side portions of the encasing detection flexible circuit board 800 are folded into the shape shown in FIGS. 13, 14. The folded portions are fixed respectively.

In FIG. 9 mentioned above, a magnetic card reading apparatus is fixedly mounted on the smart card reader. Such a magnetic card reading apparatus is adapted to read the information stored in a magnetic trace of the card. The magnetic card reading apparatus of FIG. 9 is not protected against manipulations.

FIGS. 19 to 27 disclose an embodiment of the invention which relates in particular to the protection of a magnetic card reading apparatus 500 which, see to FIG. 9, can be located on a smart card reader. The magnetic card reading apparatus 500 is, in accordance with the present invention, largely protected against manipulations by the following features. The desired manipulation security relies on the principles disclosed in connection with the manipulation safety of the preceding embodiments. In particular, attention is drawn to the design of the protective layers or the design of protective grid flexible circuit board as described in connection with FIGS. 3 and 4, and also reference is made to the operation thereof explained in connection with FIGS. 5 and 6. For all these protective layers or protective flexible printed circuits, for example also for the reader-protective flexible circuit 801 in accordance with FIG. 17 as well as the connecting protective flexible circuit 803, the grids are used which are shown with respect to the function in FIGS. 5 and 6, grid which will provide by means of a suitable signal information in case that grids are contacted or separated by means of a drill coming from the outside.

FIG. 19 shows the magnetic card reading apparatus 500 of the invention from below with respect to the direction in which it would be mounted: see FIG. 9. FIG. 23 shows the magnetic card reading apparatus 500 in a perspective from above.

The magnetic card reading apparatus 500 comprises, see FIG. 21, a magnetic head 501, of which FIG. 19 shows in substance only a slide surface which is more clearly shown in FIG. 24. The magnetic card reading apparatus 500 further comprises a magnetic head holder 502 as well as a connecting flexible circuit 504.

The magnetic head 501 comprises in general a magnetic head housing 503 made of plastic material. At the top surface of the housing 503, there are provided reading gaps 506 for cooperation with a magnetic stripe of a card as is shown in FIG. 23.

The housing 503 of the magnetic head forms at its bottom side which is shown in FIG. 21, at all four corners connecting legs 515. At the right hand side edge shown in FIG. 21, i.e. at the edge where the connecting flexible circuit 504 exits in the mounted condition, in addition to the two respective connecting legs 508 filling elements 510, 511 are provided by the housing 503 of the magnetic head, which also add to the manipulation security. Between the two filling elements 510, 511 is a ground contact 509. Further, bent connecting legs 508 are provided which in the mounted condition rest like the filling elements 510, 511—see the embodiment of FIG. 24—on the connecting flexible circuit 504. Corner legs or spacers 515 project preferably higher than the bottom side of the housing 503 of the magnetic head, higher than the supporting surfaces of the connecting legs 508 and the filling elements 510, 511.

The magnetic head 501 is fixedly mounted in a suitable manner to the magnetic head support 502 with a connecting end 550 of the magnetic head (see FIG. 22) placed in between; in particular, the connecting legs 508 and the ground contact are fixedly mounted by means of a conductive adhesive at respective connecting pads of a connecting flexible circuit 504 yet to be described. Following the fixing of the magnetic head 501 on the support 502 of the magnetic head, the magnetic head is placed with the abutment surface 522 onto the respective surface provided at the card reader and fixing occurs by means of a screw which is screwed through a mounting hole 520. The support 502 of the magnetic head comprises, as is shown in FIG. 23, a compression spring recess 521 as well as a positioning pin 523. The connecting flexible circuit board 504 has a similar structure as the detection flexible circuit 1 (also called flex-print) shown in FIG. 1 which could also be referred to as connecting flexible circuit (connecting flex-print) 1. In the embodiment of FIGS. 1 to 3, the connecting flexible circuit 1 provides also protection against manipulation for the connecting tongue shown in FIGS. 1 to 3, and also protection against manipulation is provided in the area of said part of the connecting flexible circuit 1 which projects into the smart card reader 10.

In the embodiments shown in FIGS. 7 through 16, an encasing detecting flexible circuit 800 is explained which protects the smart card reader 710 against manipulation due to the fact that the encasing detecting flexible circuit encases in a manner providing safety against manipulation the smart card reader 17 (translator: 710) such that the smart card reader 710 is protected on all sides. Similar to the embodiment shown in FIGS. 1 and 4, the connecting tongue 888 of the encasing detection flexible circuit is protected above and below by means of respective protective grids comprised of conductors in the reader-protective flexible circuit 801 and in the connecting flexible circuit 803.

One end of the connecting flexible circuit 504 comprises similar to the connecting flexible circuit of the two earlier embodiments a connection end 540 for the magnetic head and a connection tongue 542 for the magnetic head, see FIG. 22.

Similar to the embodiment according to FIGS. 7 through 16, the connecting end 540 of the magnetic head comprises means for connecting the connecting legs 508 as well as the ground contact 509 of the magnetic head 501. Moreover, the connecting end 540 of the magnetic head is designed such that the magnetic head 501 encases, similar to the encasing flexible circuit 800, the smart card reader 710 at the reading head 501 at such endangered locations. This will now be explained in some detail referring to FIGS. 24 to 27. FIG. 27 discloses a perspective view of the connecting flexible circuit 504 prior to the reading head 501 being placed on the connecting end 540 and with the reading head 501 and the magnetic head support 502 being inserted and fixedly mounted.

In FIG. 24 as well as the enlargements shown in FIGS. 25 and 26, one can recognize that the connecting flexible circuit 504 comprises a plurality of layers or films which are connected to each other. In the embodiment shown, the connecting flexible circuit 504 comprises the following five layers: A first protective layer 530, a second protective layer 531 and a third layer 532, which can also be called a connection layer or a flexible connection circuit 532, and a fourth protective layer 563 as well as a fifth protective layer 534.

The first protective layer 530 and the second protective layer 531 form a protective layer for the magnetic head, in particular a protective flexible circuit for the magnetic head. The term “protective flexible circuit” 591 for the magnetic head means that the protective flexible circuit for the magnetic head provides in particular protection also for the magnetic head 501. As can be recognized in FIG. 25, the protective flexible circuit for the magnetic head is guided around the side surfaces of the magnetic head 501 and is glued thereto and thus provides a protection against manipulation. The protective flexible circuit 591 for the magnetic head further provides on its other side in the area of the connecting tongue 542 for the magnetic head a protection against manipulation.

The flexible circuit 591 for protecting the magnetic head comprises, different from the corresponding component of the first embodiment and of the second embodiment, two layers or two films. Thus, the required protective grid for obtaining the effect represented in FIGS. 5 and 6 can be realized with one layer, while the required connections or wirings are provided in the respect second layer. At a suitable location, the connections or wirings are connected with the connecting flexible circuit 532 so as to obtain via termination contacts 536 of the connecting flexible circuit 532 the necessary information about manipulations.

The same is true for the two-layer design of the protective flexible circuit 592.

As can be recognized in FIG. 26, the five-layer design of the connecting flexible circuit 504 ends at the ground contact 509 and at the filling elements 510 and 511, respectively. Starting at this point, the flexible circuit 591 for the protection of the magnetic head and the connecting flexible circuit 532 penetrate into the magnetic card reading apparatus 501. The connecting flexible circuit 532 is electrically connected with its respective conductors or conductor paths with the connecting legs 508 and ends, as is shown in FIG. 25. Subsequently, preferably only the flexible circuit 591 for the protection of the magnetic head is folded around the side surfaces of the magnetic head 501 and is fixedly mounted thereon in a manner secure against manipulation. In FIGS. 22 and 25, it is shown in detail that the corners formed by the wings 537, 538, 539 of the flexible circuit 591 for the protection of the magnet cooperate with the corner feet 515 to provide for a secure mounting of the connecting end 550 of the magnetic head.

1. A smart card reader having a housing in which contact elements are arranged which are adapted to contact a smart card, and adapted to be electrically connected to termination means wherein a protective grid is provided which encases the housing at least in an area where undesired manipulations are expected and wherein preferably also the termination means are encased.

2. The smart card reader of claim 1, wherein the termination means are a flexible printed circuit.

3. The smart card reader of claim 1, wherein the protective grid comprises closely arranged electrical conductors or conductive paths, the separation and or short-circuiting thereof can be determined from the outside due to a change of the electrical characteristics of the protective grid thus indicating attempts to manipulate.

4. The smart card reader of claim 1 wherein the protective grid is formed in an encasing flexible circuit which encases the housing and the termination means.

5. The smart card reader according to claim 1, wherein the protective grid is realized in an integral encasing flexible circuit comprising a protective reader flexible circuit, a connecting flexible circuit and a protective connecting flexible circuit.

6. The smart card reader of claim 1, wherein the protective reader flexible circuit forms, when encasing the smart card reader, the outer layer, and wherein the protective connecting flexible circuit is formed only in the area of the termination means and the connecting flexible circuit.

7. The smart card reader of claim 1, wherein the encasing flexible circuit comprises a generally rectangular shape and forms two main sections, one of the main sections covering the bottom side and the other one of the main sections covering the top side of the smart card reader, and wherein further the encasing flexible circuit comprises sections which can be folded about the side edges of the smart card reader, said foldable sections being adapted to be fixed at mounting means formed by the smart card reader housing.

8. The smart card reader as set forth in claim 1, wherein the encasing flexible circuit comprises two reinforcement elements, one of which provides a cover for the upper sides of the smart card reader.

9. The smart card reader of claim 1, wherein the connecting tongue of the connecting flexible circuit extending out of the smart card reader is soldered with its contact pads to the contact pads of the connecting flexible circuit such that the protective reader flexible circuit provides protection against manipulation for the connecting tongue, and whereby the encasing flexible circuit forms a connecting tongue which provides the electrical connection of the protective smart card reader with another apparatus.

10. The smart card reader of claim 1, wherein the connecting tongue of the smart card reader comprises termination or connecting zones for the connectors extending out of the reader and wherein a connecting tongue of the connecting flexible circuit is protected on one side by the grid of the protective reader flexible circuit, while on the other side the protection is provided by a protective connecting flexible circuit which is also provided with a protective grid which is connected via the connecting flexible circuit with the protective reader flexible circuit, and wherein the protective grids are accessible from the outside via the contact pads of the connecting flexible circuit.

11. The smart card reader according to claim 1, wherein the connecting tongue of the flexible circuit is soldered the connecting pads in the connecting flexible circuit.

12. A flexible circuit for the connection to an electric or electronic apparatus, in particular a smart card reader, said flexible circuit comprising at least one data transfer layer adapted to be connected to said apparatus and at least one protective layer comprising a protective grid.

13. The flexible circuit of claim 12, wherein the data transfer layer formed as a middle layer is provided on one side with a protective layer and on the other side with a protective layer.

14. The flexible circuit of claim 12, wherein in the protective layers conductors or conductor paths are embedded which form a protective grid such that the penetration of metal parts, can be detected.

15. The flexible circuit as set forth in claim 12, wherein the connectors in the protective layers are arranged closely to each other such that even the penetration of smaller drill bits can be detected.

16. The flexible circuit according to claim 12 wherein the conductors of the protective layers are accessible via contact pads or zones provided at the central or middle layer.

17. An electric termination or connection component, in particular a connection flexible circuit; an encasing flexible circuit, a detection flexible circuit for an apparatus, in particular a smart card reader and/or a magnetic card reading apparatus, wherein said connecting flexible circuit comprises: a connecting tongue projecting out of the apparatus and comprising a connecting end adapted to be connected to an apparatus, and wherein the connecting flexible circuit comprises at least one connecting layer which contains conductors or conductor paths which can be connected to said apparatus and which further comprises conductors or conductor paths which end at the contact pads or zones of the termination tongue, and wherein the connecting flexible circuit is further provided on one side and/or on both sides with layers or flexible circuits comprising protective grids so as to indicate manipulations.

18. The magnetic card reading apparatus of claim 17, wherein a connecting flexible circuit is provided with a connecting end for the magnetic head, said connecting end being provided with connecting zones which are adapted for electrical connection with connecting legs of a magnetic head and wherein further the connecting end of the magnetic head comprises a flexible circuit for the protection of the magnetic head, said flexible circuit being adapted to encase the magnetic head in a manner providing security against manipulations.

19. The magnetic card reading apparatus of claim 18, wherein the flexible circuit for the protection of the magnetic head covers the side of the magnetic head from which the connecting legs of the magnetic head project and wherein the flexible circuit for the protection of the magnetic head forms wings which encase the magnetic head from its sides.

20. The magnetic card reading apparatus of claim 19, wherein in the corners of the magnetic head are provided with corner feet which fit into cut-outs formed by the wings.

21. The magnetic card reading apparatus of claim 20, wherein the connecting flexible circuit consists in substance of a flexible circuit for the protection of the magnetic head, a connecting flexible circuit and a further protective flexible circuit in this sequence.

22. The magnetic card reading apparatus of claim 21, wherein both the flexible circuit for the magnetic head as well as the protective flexible circuit each comprise for instance two layers wherein protective grids can be provided both in the flexible circuit for the protection of the magnetic head as well as in the protective flexible circuit.
